(19) United States
(12) Patent Application Publication
(10) Pub. No.: US 2009/0294910 A1
(43) Pub. Date: Dec. 3, 2009

(54) SILICON WAFER

(75) Inventors: Takeo KATOH, Tokyo (JP); Kazushige TAKAISHI, Tokyo (JP)

Correspondence Address: GREENBLUM & BERNSTEIN, P.L.C., 1950 ROLAND CLARKE PLACE, RESTON, VA, 20191, US

(73) Assignee: SUMCO CORPORATION, Tokyo (JP)

(21) Appl. No.: 12/476,452

(22) Filed: Jun. 2, 2009

(30) Foreign Application Priority Data
Jun. 3, 2008 (JP) 2008-146227

(51) Int. Cl. H01L 23/00

(52) U.S. Cl. 257/618; 257/E23.002

(57) ABSTRACT

A reinforcement member made with silicon carbide different from silicon is installed on the back face of a silicon wafer, thereby the silicon wafer is increased in Young's modulus and the wafer is less likely to deflect.

### CROSS-REFERENCE TO RELATED APPLICATIONS

The present application claims priority under 35 U.S.C. §119 of Japanese Application No. 2008-146227 filed on Jun. 3, 2008, the disclosure of which is expressly incorporated by reference herein in its entirety.

### BACKGROUND OF THE INVENTION

1. Field of the Invention

The present invention relates to a silicon wafer and, more particularly, to a silicon wafer which is higher in rigidity and less likely to deflect than conventional wafers when the silicon wafer is kept horizontal and simply supported.

2. Description of the Related Art

In a device process, on exposure, a stepper (reduced projection exposure apparatus) is, for example, used to irradiate light irradiated from an exposing source on a pattern formed on a mask (reticle), thus reducing light passed through the pattern by means of a reduced projection lens, thereafter transferring the light to the surface of a silicon wafer on which a photo resist is coated (refer to Japanese Patent Laid-Open No. 2005-228978, for example).

As shown in FIG. 9, a silicon wafer 100 shipped from a wafer production plant is a CZ wafer (based on the CZ Czochralski system) which is 300 mm in diameter, 775 μm in thickness and approximately 110 GPa in Young's modulus (modulus of longitudinal elasticity).

On exposure, the silicon wafer 100 is simply supported on a wafer stage arranged below the stepper by means of six supporting pins 101 placed at every 60 degrees circumferentially on the stage (circumferential direction of the wafer) in a state that its own weight only acts on the outer circumference.

As described so far, the conventional silicon wafer 100 is a CZ wafer, the Young's modulus of which is approximately 110 GPa. Therefore, for example, for a next-generation silicon wafer which is 450 mm or more in diameter, where an outer circumference of the wafer is simply supported on a wafer stage of the stepper, the silicon wafer 100 (indicated by the double dotted & dashed line in FIG. 9) in which the surface 100a and the back face 100b are arranged horizontally has been deflected due to its own weight (indicated by the solid line in FIG. 9). As a result, the resolution of a pattern is decreased in an outer circumferential part of the wafer and the depth of focus is decreased, thus making it difficult to secure the pattern at high accuracy.

### SUMMARY OF THE INVENTION

Under the above-described circumstances, as a result of intensive research, the inventor focused attention on the back-face structure of a wafer at which a silicon wafer is increased in rigidity. More specifically, the inventor found that if a reinforcement member different in material from silicon is installed on the back face of the silicon wafer or a concave-convex portion for reinforcement for increasing the rigidity of the silicon wafer is formed, by which the silicon wafer is increased in rigidity as a whole as compared with a conventional wafer, and where the silicon wafer is simply supported, the wafer is less likely to deflect, thereby accomplishing a non-limiting facet of the present invention.

A non-limiting feature of the present invention is to provide a silicon wafer which is higher in rigidity and less likely to deflect than a conventional silicon wafer.

A non-limiting aspect of the present invention provides a silicon wafer in which a reinforcement member formed with a material different from silicon to increase the rigidity of the silicon wafer is installed on the back face of the silicon wafer.

According to this non-limiting aspect of the present invention, the reinforcement member made with a material different from silicon is installed on the back face of the silicon wafer so as not to be separated. As a result, Young's modulus of the silicon wafer is increased as compared with a conventional silicon wafer which is devoid of the reinforcement member on the back face.

Therefore, for example, on exposure in a device forming process, when the wafer is kept horizontal and simply supported on a wafer stage of a stepper so that only its own weight can act thereon, the wafer is less likely to deflect as compared with a conventional silicon wafer.

Single crystal silicon wafers and polycrystalline silicon wafers may be adopted as silicon wafers. The surface of the silicon wafer is subjected to a mirror finish.

A silicon wafer is available in a variety of diameters, for example, 200 mm, 300 mm and 450 mm.

The expression that “higher in rigidity than a silicon wafer” means that it is less likely to be deformed by shearing force as compared with the silicon wafer. In other words, Young's modulus of the silicon wafer after reinforcement by a reinforcement member is higher than that of the silicon wafer before reinforcement (100 GPa or more but lower than 120 GPa).

Young's modulus of a silicon wafer after reinforcement is preferably from 120 to 1000 GPa. Where Young's modulus is less than 120 GPa, there is found no great difference in the amount of deflection as compared with silicon wafers which are not subjected to the treatment of the present invention. Further, where Young's modulus is in excess of 1000 GPa, the amount of deflection will hardly vary. Young's modulus of the silicon wafer after reinforcement is preferably from 120 to 500 GPa. Where Young's modulus is within the above range, the wafer carrying and wafer production processes under the same conditions as those of conventional wafers can be applied.

“A material different from silicon” may include silicon carbide (SiC), silicon oxide (SiOx), silicon nitride (SiNx) and poly silicon (poly Si).

The reinforcement member is preferably a material which is higher in rigidity than the silicon wafer in terms of comparison of Young's modulus by using a same-sized specimen of the silicon wafer and that of a material. However, such a material may be acceptable that is equal to or lower than the silicon wafer in rigidity.

The reinforcement member may be installed all over the back face of the silicon wafer so as not to be separated or may be installed only partially on the back face of the silicon wafer so as not to be separated. Where the reinforcement member is installed partially on the back face of the wafer, it is preferable that the reinforcement member is laid across the both ends of the back face of the silicon wafer because the silicon wafer is increased in rigidity as compared with a case where it is not laid across as described above.

A shape of the reinforcement member when viewed from the front (front view) may include, for example, a lattice shape and a concentrically connected shape.

The reinforcement member is preferably from 0.1 to 50 μm in thickness. Where the thickness is less than 0.1 μm, it is difficult to obtain the effects of the present invention. Further, where the thickness is in excess of 50 μm, the wafer structure in itself is greatly different in thickness, and conventional processes are not usable as they are.

A method for forming the reinforcement member on the back face of the silicon wafer includes a method in which a mask is formed, for example, on the back face of the wafer, thereafter a material of the reinforcement member is deposited on a part of forming the reinforcement member by a CVD (chemical vapor deposition) method. Further, there may be also adopted a method in which the reinforcement member is deposited all over the back face of the wafer by the CVD method, thereafter, the surface of the reinforcement member is covered with a mask and unwanted parts are subjected to etching.

The reinforcement member may include a material which is made up of a plurality of band members passing through the center of the back face of a silicon wafer.

Since the reinforcement member passes through the center of the back face of the wafer, it is possible to effectively reduce the deflection of the wafer due to its own weight. Thereby, the silicon wafer can be further increased in rigidity compared with a case where the reinforcement member does not pass through the center of the back face of the wafer.

The band member is from 1 μm to 5 cm in width. Where the width is less than 1 μm, it is difficult to obtain the effect of increasing the rigidity of the silicon wafer. Further, where the width is in excess of 5 cm, in-plane non-uniformity is developed as properties of the wafer. The band member is preferably from 10 μm to 1 cm in width. Where the width is in the above range, there is obtained a good balance between the effect of increasing the rigidity of the silicon wafer and in-plane uniformity of the wafer.

The band member is from 0.1 to 50 μm in thickness. Where the thickness is less than 0.1 μm, it is difficult to obtain the effect of increasing the rigidity of the silicon wafer. Further, where the thickness is in excess of 50 μm, the wafer structure is increased in thickness as a whole, thus resulting in problems in wafer production processes. The band member is preferably from 0.5 to 25 μm in thickness. Where the thickness is in this range, the effect of increasing the rigidity of the silicon wafer is well obtained to reduce the problems in wafer production processes.

A shape of the reinforcement member on the back face of the wafer (arrangement of each of the band members) may include, for example, a lattice shape, a cross shape, a stripe shape and a concentrically connected shape. Of these shapes, the lattice shape is most preferable because of the easy formation on the back face of the wafer.

Another non-limiting aspect of the present invention provides a silicon wafer in which a concave-convex portion for reinforcement for increasing the rigidity of the silicon wafer is formed on the back face of the silicon wafer.

According to this non-limiting aspect, since the concave-convex portion for reinforcement is formed on the back face of the silicon wafer, the silicon wafer is less likely to be deformed and increased in Young's modulus than conventional silicon wafers. Therefore, for example, on exposure in a device forming process, when the wafer is kept horizontal and simply supported on a wafer stage of a stepper so that only its own weight acts, the wafer is less likely to deflect as compared with conventional silicon wafers.

The concave-convex portion for reinforcement is a design formed in a concave-convex shape on the back face of the wafer and different from that fixed on the back face of the silicon wafer in separation from the silicon wafer.

A shape of the concave-convex portion for reinforcement may include, for example, a circular shape, an oval shape, a triangular shape, a polygonal shape greater than a rectangular shape in a planar view and any other given shape. Any size of the concave-convex portion will be acceptable.

The concave-convex portion for reinforcement may be formed all over on the back face of the wafer or may be formed only partially on the back face of the wafer.

A method for forming the concave-convex portion for reinforcement may include, for example, a method in which a mask is formed on the back face of the silicon wafer and a recess is etched on the back face of the wafer. A sandblasting method can also be adopted.

The concave-convex portion for reinforcement may include that which is formed in a waffle shape made up of a lattice-shaped projected streak portion and a flat bottom portion enclosed by the projected streak portion or that which is formed in a corrugated plate shape in which peaks and valleys continue in a gently undulating manner.

Where the concave-convex portion for reinforcement is in a waffle shape, the concave-convex portion for reinforcement is given a higher wafer in-plane uniformity. Further, where the concave-convex portion for reinforcement is in a corrugated panel shape, the concave-convex portion for reinforcement is given a higher wafer in-plane uniformity and also provided with a smaller number of corners on the back face of the wafer than in the waffle shape, thus the occurrence of dust is in a smaller amount.

In the waffle shape, the projected streak portion is from 0.1 to 10 μm in height. Where the height is in excess of 10 μm, it is difficult to produce wafers.

The projected streak portions are formed at a pitch of 0.1 mm to 50 mm. Where the pitch is less than 0.1 mm, it is difficult to obtain the effect of the present invention. Further, where the pitch is in excess of 50 mm, there is a lower wafer in-plane uniformity.

In the corrugated plate shape, the peaks and valleys are formed at a pitch of 0.1 to 50 mm. Where the pitch is less than 0.1 mm, it is difficult to obtain the effect of the present invention. Further, where the pitch is in excess of 50 mm, there is a lower wafer in-plane uniformity.

A difference in height between the peaks and valleys is 0.1 to 10 μm. Where the difference in height is less than 0.1 μm, it is difficult to obtain the effect of the present invention. Further, where the difference in height is in excess of 10 μm, it is difficult to produce wafers.

The expression “peaks and valleys continue in a gently undulating manner” refers to a state where the peaks and valleys continue endlessly without any step.

### BRIEF DESCRIPTION OF THE DRAWINGS

The present invention is further described in the detailed description which follows, in reference to the noted plurality of drawings by way of non-limiting examples of exemplary embodiments of the present invention, in which like reference numerals represent similar parts throughout the several views of the drawings, and wherein:

FIG. 1 is a perspective view showing a silicon wafer of an example 1 of the present invention, when viewed from the back face;

FIG. 2 is a cross sectional view showing the silicon wafer of the example 1 of the present invention;

FIG. 3 is a cross sectional view showing a state where the silicon wafer of the example 1 of the present invention is simply supported;

FIG. 4 is a perspective view showing another silicon wafer of the example 1 of the present invention, when viewed from the back face;

FIG. 5 is a perspective view showing still another silicon wafer of the example 1 of the present invention, when viewed from the back face;

FIG. 6 is a perspective view showing further still another silicon wafer of the example 1 of the present invention, when viewed from the back face;

FIG. 7 is a perspective view showing a silicon wafer of an example 2 of the present invention, when viewed from the back face;

FIG. 8 is an enlarged cross sectional view showing major parts of still another silicon wafer of the example 2 of the present invention; and

FIG. 9 is a cross sectional view showing a state before and after a conventionally produced silicon wafer is simply supported.

### DETAILED DESCRIPTION OF THE INVENTION

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description is taken with the drawings making apparent to those skilled in the art how the forms of the present invention may be embodied in practice.

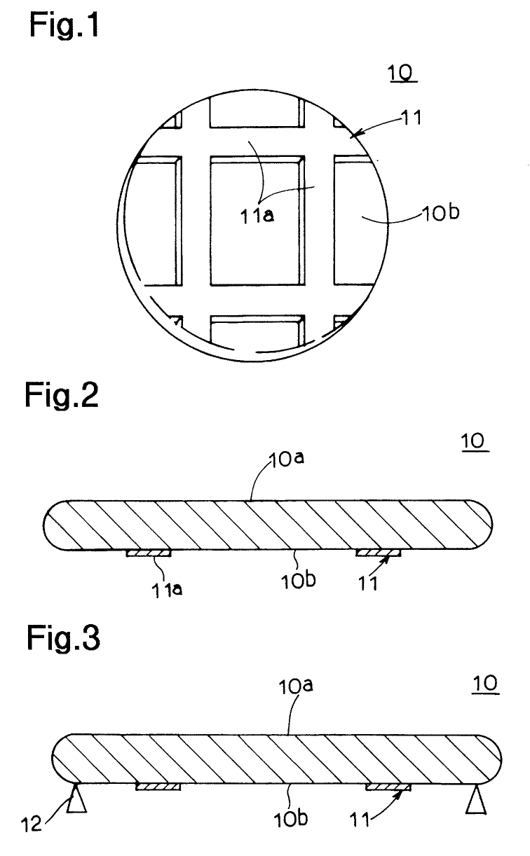

In FIG. 1 and FIG. 2, the numeral 10 depicts a silicon wafer of the example 1 of the present invention, and the silicon wafer 10 is a wafer formed by using a material different from silicon and a reinforcement member 11 for increasing the rigidity of the silicon wafer 10 is also installed on the back face of the wafer. The reinforcement member 11 is made up of four band members (membranes) 11a installed on the back face of the wafer 10b in a lattice shape.

Hereinafter, a detailed description will be given for the silicon wafer 10.

The silicon wafer 10 is a single crystal CZ wafer (based on the Czochralski system), whose surface (device forming face) 10a is mirror-finished and which is 450 mm in diameter, 10Ω·cm in specific resistance, p-type, 10×10¹⁷ atmos/cm³ in solid solubility oxygen concentration, and 110 GPa in Young's modulus. The silicon wafer 10 is produced in steps in which silicon single crystals taken up from a melt in a crucible are subjected to outer circumference cutting, cutting into blocks and slicing in a sequential manner to give wafers and these wafers are sequentially subjected to various processes such as beveling, lapping, etching and grinding.

The reinforcement member 11 is made with silicon carbide (SiC) and obtained by connecting four band members 11a which are 10 mm in width and 10 μm in thickness and installed on an outer circumference of the back face of the wafer 10b so as not to be separated from the silicon wafer 10 in a lattice form, when viewed from the front (front view). The silicon carbide-made reinforcement member 11 is a member which is higher in rigidity by approximately 20% than the silicon wafer 10 in terms of comparison of Young's modulus by using a same-sized specimen of the silicon wafer 10 and that of the reinforcement member.

A method for forming the reinforcement member 11 is shown as follows. More specifically, silicon carbide is deposited on the back face 10b of the silicon wafer 10 after polishing according to a CVD method. Thereby, the silicon wafer 10 is increased in Young's modulus up to 150 GPa. Further, in place of silicon carbide, a silicon nitride membrane or a silicon oxide membrane may be deposited on the back face 10b of the silicon wafer 10 according to the CVD method, thereby giving the band member 11a.

The thus produced silicon wafer 10 is transported to a device process where a device is formed on the wafer surface 10a. On exposure thereof, the silicon wafer 10 is simply supported from below on a wafer stage arranged below a stepper by using six supporting pins 12 placed at every 60 degrees circumferentially on the stage (circumferential direction of the wafer), with the outer circumference of the wafer kept below (FIG. 3). Light irradiated from an exposing source passes through a pattern formed on a mask, reduced by a reduced projection lens, thereafter, irradiated on the surface 10a on which a photo resist of the silicon wafer 10 is coated, by which the pattern is transferred.

As described above, the silicon carbide-made reinforcement member 11 different from silicon is installed on the back face 10b of the silicon wafer 10 so as not to be separated, by which the silicon wafer 10 is increased in apparent Young's modulus by approximately 20% as compared with a conventional silicon wafer 10 which is devoid of the reinforcement member 11.

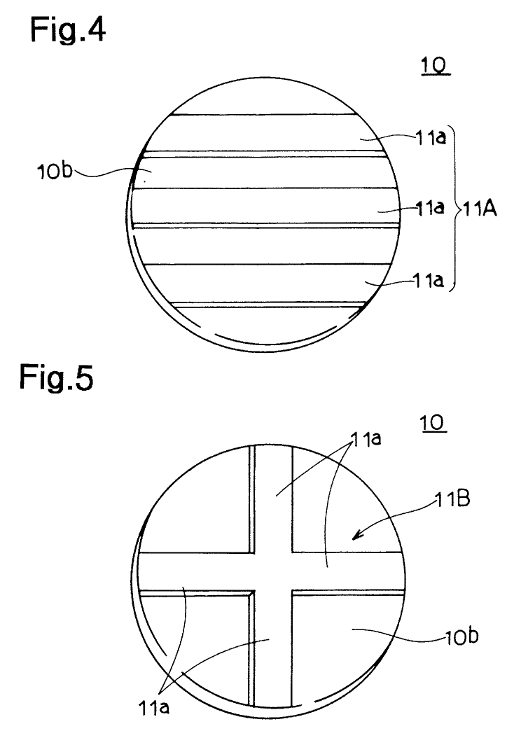

As another type of the reinforcement member, there may be adopted a stripe-shaped reinforcement member 11A in which three band members 11a are spaced apart in parallel (FIG. 4). Further, there may be adopted a cross-shaped reinforcement member 11B which is provided with four band members 11a extending radially at intervals every 90 degrees, with the central part of the back face of the wafer 10b placed at the center (FIG. 5). Since the band members 11a are arranged in a cross shape, it is possible to increase the rigidity of the silicon wafer 10 in the width direction of the band members 11a, which is a disadvantage of the stripe-shaped reinforcement member 11A illustrated in FIG. 4. Further, the reinforcement member 11A passes through the center of the back face of the wafer 10b, by which a part exhibiting the greatest deflection can be reinforced. Thereby, there is an increase in the rigidity of the wafer as compared with a case where the reinforcement member 11A does not pass through the center of the back face of the wafer 10b.

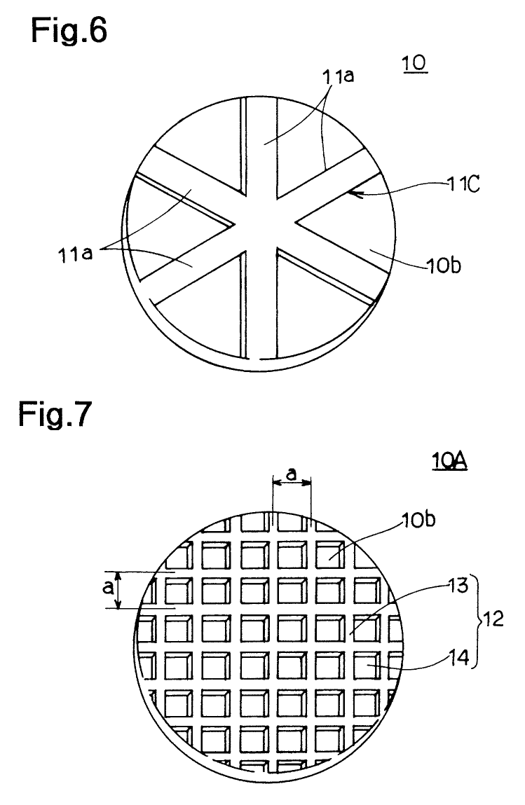

As still another type, there may be adopted an asterisk-shaped reinforcement member 11C which extends radially at intervals every 60 degrees passing through the central part of the back face of the wafer 10b and composed of six band members 11a (FIG. 6). This reinforcement member is further increased in rigidity of the silicon wafer 10 extending all over in the circumferential direction of the wafer than the reinforcement member illustrated in FIG. 5.

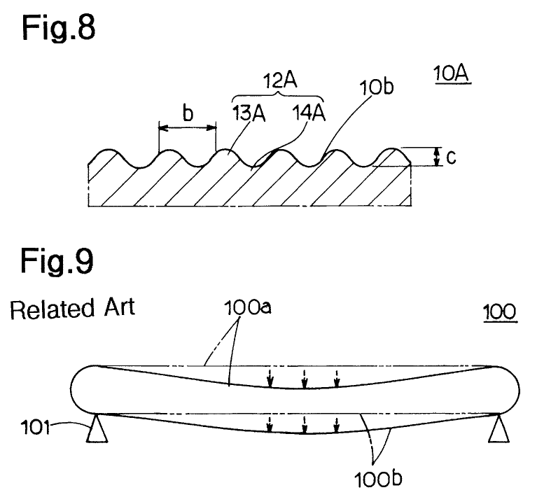

Next, a description will be given for a silicon wafer of an example 2 of the present invention by referring to FIG. 7 and FIG. 8.

As shown in FIG. 7, a silicon wafer 10A of the example 2 of the present invention is that in which a concave-convex portion for reinforcement 12 for increasing the rigidity of the silicon wafer 10A is formed all over on the back face 10b of the silicon wafer 10A.

The concave-convex portion for reinforcement 12 is formed in a waffle shape made up of a lattice-shaped projected streak portion 13 and many flat bottom portions 14 enclosed with the projected streak portion 13. The projected streak portion 13 is 1 mm in width and 5 μm in height. The projected streak portion 13 is formed at a pitch of 1 mm in the horizontal and vertical directions. As described so far, since the concave-convex portion for reinforcement 12 is formed in a waffle shape, wafer in-plane uniformity can be sufficiently secured to decrease the deflection.

As another type of the concave-convex portion for reinforcement, there may be also adopted a corrugated plate-shaped concave-convex portion for reinforcement 12A in which peaks 13A and valleys 14A continue in a gently undulating manner (FIG. 8). The peaks 13A and the valleys 14A are formed at a pitch b of 1 mm. Further, a difference c in height between the peaks 13A and the valleys 14A is 10 μm. As described above, as the concave-convex portion for reinforcement 12A, adopted is that which is formed in a corrugated plate shape so that the peaks 13A and the valleys 14A continue in a gently undulating manner, thereby the wafer in-plane uniformity can be sufficiently secured to decrease the deflection of the silicon wafer 10A and also reduce the possible occurrence of dust.

A description on the constitution, actions and effect will be omitted here because they are substantially similar to those of the example 1.

It is noted that the foregoing examples have been provided merely for the purpose of explanation and are in no way to be construed as limiting of the present invention. While the present invention has been described with reference to exemplary embodiments, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular structures, materials and embodiments, the present invention is not intended to be limited to the particulars disclosed herein; rather, the present invention extends to all functionally equivalent structures, methods and uses, such as are within the scope of the appended claims.

The present invention is not limited to the above described embodiments, and various variations and modifications may be possible without departing from the scope of the present invention.

What is claimed is:

1. A silicon wafer, wherein a reinforcement member formed with a material different from silicon to increase the rigidity of the silicon wafer is installed on the back face of the silicon wafer.

2. A silicon wafer, wherein a concave-convex portion for reinforcement for increasing the rigidity of the silicon wafer is formed on the back face of the silicon wafer.
